(19) United States
(12) Patent Application Publication
(10) Pub. No.: US 2025/0180648 A1
(43) Pub. Date: Jun. 5, 2025

(54) MOTOR MONITORING DEVICE

(71) Applicant: FANUC CORPORATION, Yamanashi (JP)

(72) Inventors: Kenji SHIMIZU, Yamanashi (JP); Makoto HAGA, Yamanashi (JP)

(73) Assignee: FANUC CORPORATION, Yamanashi (JP)

(21) Appl. No.: 18/842,372

(22) PCT Filed: Apr. 27, 2022
(86) PCT No.: PCT/JP2022/019052

§ 371 Date: Aug. 28, 2024

(51) Int. Cl. G01R 31/34

(52) U.S. Cl. CPC G01R 31/343

(57) ABSTRACT

A motor monitoring device according to one aspect of the present disclosure comprises: a rotational speed acquisition unit that acquires the rotational speed of a motor of a machine tool; an output value acquisition unit that acquires the output value of the motor; a state value acquisition unit that acquires a state value indicating the state of the motor; and a graph display unit that plots a marker indicating a combination of the rotational speed and the output value in a graph region in which one axis is the rotational speed and the other axis is the output value. The graph display unit comprises: a graph region setting unit which, with regard to anticipated combinations of the rotational speed and the output value, divides the graph region into a plurality of load zones with different load levels on the basis of a plurality of time ratings of the motor, and displays the plurality of load zones in an identifiable manner; and a plotting unit that changes and plots the mode of the marker according to the state value.

### TECHNICAL FIELD

The present invention relates to a motor monitoring device.

### BACKGROUND ART

In motors such as spindle motors used in machine tools, where the load can significantly vary, there is a risk of overheating if a high load state persists and heat accumulates. Various time ratings can be set for such motors to ensure operation without overheating under specific conditions. For example, the time ratings specified in JIS-C4034-1 include continuous ratings enabling continuous operation, short-time ratings enabling operation for a certain period (load time) in a case where the operation starts at room temperature, and repetitive ratings enabling operation for a certain period (load time ratio) within a specified cycle time.

It has been proposed to estimate the time until a motor overheats while maintaining the current operational state (see, for example, Patent Document 1). Knowing the time until overheating can help determine whether the current machining operation can be completed.

### CITATION LIST

### Patent Document

Patent Document 1: Japanese Patent No. 5628994

### DISCLOSURE OF THE INVENTION

### Problems to be Solved by the Invention

However, estimating only the time until overheating does not allow for easily understanding the motor's operational safety and margin. Specifically, when the settings such as motor speed is adjusted to maximize the efficient machining while minimizing the margin for overheating, it is not easy to determine how much the set values should be increased or decreased. Therefore, a technique that allows for easily understanding the motor's state is desired.

### Means for Solving the Problems

One aspect of the present disclosure provides a motor monitoring device, which includes: a rotation number acquisition unit that acquires a rotation number of a motor; an output value acquisition unit that acquires an output value of the motor; a state value acquisition unit that acquires a state value indicating the motor's condition; and a graph display unit that plots markers indicating a combination of the rotation number and the output value on a graph area with one axis representing the rotation number and the other axis representing the output value. The graph display unit includes: a graph area setting unit that divides the graph area into a plurality of load zones with different load levels, based on a plurality of time ratings of the motor, regarding the expected combinations of the rotation number and the output value, and distinguishably displays the plurality of load zones; and a plot unit that plots the markers by changing the appearance of the markers, based on the state value.

### Effects of the Invention

According to the present disclosure, the motor's state can be easily understood.

### BRIEF DESCRIPTION OF THE DRAWINGS

FIG. 1 is a block diagram illustrating the configuration of a machine tool including a motor monitoring device according to the first embodiment of the present disclosure; and

FIG. 2 is a diagram illustrating a screen displayed by the motor monitoring device of FIG. 1.

### PREFERRED MODE FOR CARRYING OUT THE INVENTION

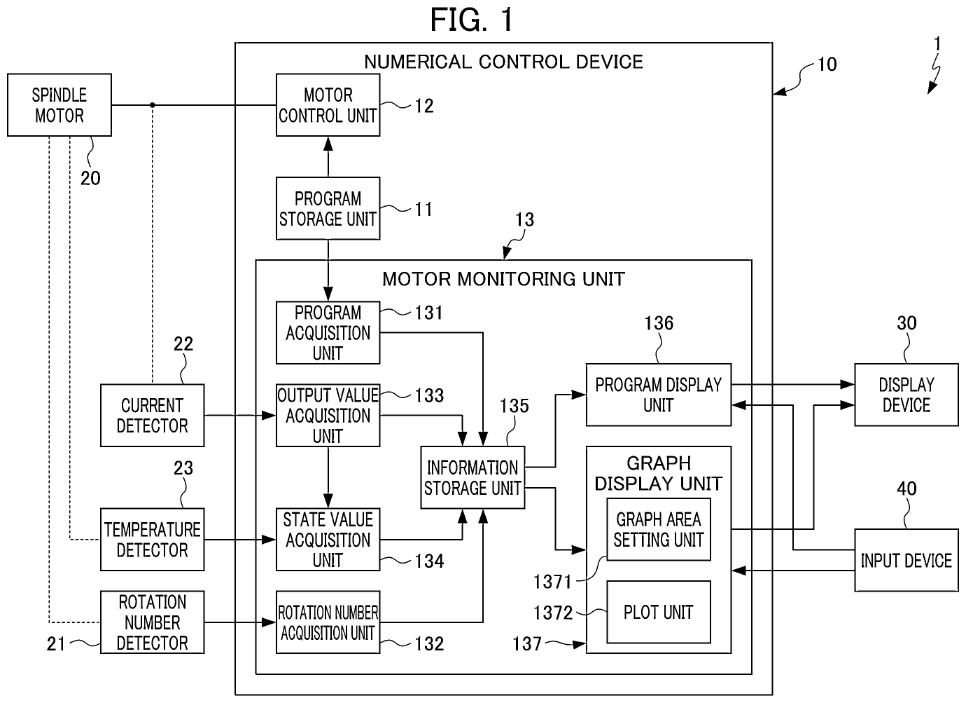

Hereinafter, embodiments of the present disclosure will be described with reference to the drawings. FIG. 1 is a block diagram illustrating the configuration of a machine tool 1 including a motor monitoring device according to the first embodiment of the present disclosure.

The machine tool 1 includes a numerical control device 10 as an embodiment of the motor monitoring device according to the present invention, a spindle motor 20, a rotation number detector 21 that detects the rotation number of the spindle motor 20, a current detector 22 that detects the current of the spindle motor 20, a temperature detector 23 that detects the winding temperature of the spindle motor 20, a display device 30 that displays a screen in accordance with the numerical control device 10, and an input device 40 used by the user to input into the numerical control device 10.

The numerical control device 10 includes a memory, a processor (CPU), input/output interfaces, etc., and can be implemented by one or more computer devices executing appropriate control programs. Components of the numerical control device 10 described below are categorized based on the functions of the numerical control device 10 and need not be distinctly separable in physical configuration and program configuration.

The spindle motor 20 is typically a motor that rotationally drives a cutting tool or workpiece, in which the load may potentially fluctuate based on the machining conditions independently of the rotation number. The rotation number detector 21, the current detector 22, and the temperature detector 23 can each be composed of well-known sensors.

The display device 30 is a well-known display that displays in accordance with signals input from the numerical control device 10. The display device 30 may be integrated with the numerical control device 10. The input device 40 is a device used by the user to input information into the numerical control device 10 and may be composed of well-known components such as a keyboard or mouse. The input device 40 may also be integrated with the numerical control device 10. The input device 40 may also be integrated with the display device 30. Specifically, the display device 30 and the input device 40 may be a single input/output device such as a touch panel.

In the present embodiment, the numerical control device 10 includes: a program storage unit 11; a motor control unit 12 that controls the operation of motors that drive the drive axes of the machine tool 1 including the spindle motor 20; and a motor monitoring unit 13 that executes the functions of the motor monitoring device according to the present disclosure.

The program storage unit 11 stores machining programs executed by the machine tool 1. Each machining program includes a plurality of blocks that specify the unit operations of the machine tool 1. Each block includes one or more words formed by combinations of a plurality of characters (letters). Typically, each block is prefixed with a sequence number to identify the block.

The motor control unit 12 executes the machining procedures described in the machining program by controlling the spindle motor 20 and the motors of other drive axes of the machine tool 1 in accordance with the machining program. The configuration of the motor control unit 12 is the same as that of well-known numerical control devices, thus a detailed description is omitted.

The motor monitoring unit 13 includes a program acquisition unit 131, a rotation number acquisition unit 132, an output value acquisition unit 133, a state value acquisition unit 134, an information storage unit 135, a program display unit 136, and a graph display unit 137.

The program acquisition unit 131 acquires a machining program from the program storage unit 11 that specifies the operation to be monitored for the spindle motor 20. In other words, the program acquisition unit 131 loads the target machining program into the working memory.

The rotation number acquisition unit 132 acquires the rotation number of the spindle motor 20 from the rotation number detector 21. The rotation number acquisition unit 132 may also acquire the rotation number of the spindle motor 20 via the motor control unit 12.

The output value acquisition unit 133 acquires the output values of the spindle motor 20, such as a current value, a power value, and a torque value. In the present embodiment, the output value acquisition unit 133 is configured to acquire the current value of the spindle motor 20 from the current detector 22 and to use the power value and the torque value calculated from the current value as the output value. However, the output value acquisition unit 133 may be configured to use the detected value such as the current value directly as the output value. The output value acquisition unit 133 may also acquire the output value or the values necessary to calculate the output value from the motor control unit 12. The types of output values acquired by the output value acquisition unit 133 may be one type or three or more types.

The state value acquisition unit 134 acquires state values indicating the conditions of the spindle motor 20. In the present embodiment, the state value acquisition unit 134 calculates the estimated time until the spindle motor 20 reaches the overheating temperature in a case where the rotation number and the output values are maintained at present values by the spindle motor 20, based on the winding temperature of the spindle motor 20 acquired from the temperature detector 23 and the current value or the output value acquired by the output value acquisition unit 133, and uses this estimated time as the first state value. The state value acquisition unit 134 calculates the torque of the spindle motor 20, based on the current value acquired by the output value acquisition unit 133, and uses this torque as the second state value. The state value acquisition unit 134 may use other indicators of the conditions of the spindle motor 20 as state values, such as using the winding temperature of the spindle motor 20 directly as the state value.

The information storage unit 135 stores the rotation number acquired by the rotation number acquisition unit 132, the output value acquired by the output value acquisition unit 133, and the state value acquired by the state value acquisition unit 134, in association with information that identifies the corresponding block of the machining program acquired by the program acquisition unit 131, such as sequence numbers or line numbers. In other words, the information storage unit 135 stores the rotation number, the output value, and the state value, so as to allow for identifying which block of the machining program was being executed when such a value was obtained. For example, the information storage unit 135 may be configured to store table data with the data items including the rotation number, the output value, the state value, and the sequence number.

Typically, since the rotation number, output value, and state value are acquired in short cycles, a plurality of combinations of rotation number, output value, and state value may be acquired for one block. However, the information storage unit 135 may store one set of data per block as a unique key, ensuring no duplicate sequence numbers between data. In this case, the representative values of the rotation number, output value, and state value corresponding to each block are stored. The representative values for the rotation number, output value, and state value should preferably indicate a higher load among the values corresponding to that block (the maximum value for rotation number, current value, and temperature, and the minimum value for estimated time) in order to ensure safety.

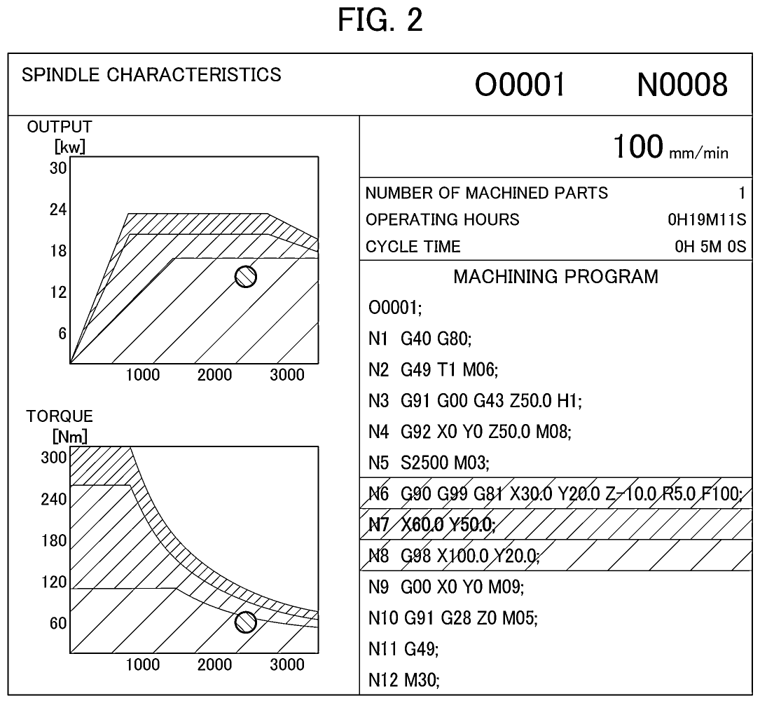

The program display unit 136 displays the program portion information, including a portion of the machining program or information indicating a position (such as a line number) of the portion, on the display screen of the display device 30. In other words, the program display unit 136 creates data of at least part of the screen displayed on the display device 30. Typically, as illustrated in FIG. 2, the program display unit 136 sets a program display area of a certain size on the display screen of the display device 30, and displays the program portion information including the machining program for lines as permitted in the program display area. The program display unit 136 may display the machining program including information such as sequence numbers as the program portion information, may extract and display only the words specifying operations of the machine tool from the machining program, may display only information indicating the position in the machining program such as sequence numbers or line numbers, or may be configured to switch between these display modes.

The program display unit 136 preferably displays the position in the machining program, for which the user wishes to check in detail, so as to be selectable by units such as characters, words, or blocks, and may be configured to allow the user to select a plurality of blocks. The result of selecting the position in the machining program by the user may be reflected in the details displayed by the graph display unit 137 as described later.

The program display unit 136 is preferably configured to accept edits to the machining program. In other words, the program display unit 136 is preferably configured to allow the user to select and rewrite words or text displayed, and to store the rewritten machining program in the program storage unit 11.

The program display unit 136 may display the program portion information in a manner that allows for distinguishing the magnitude of the rate of change of at least one of the rotation number or the output value. As a specific example, the program display unit 136 may change the color or pattern of the characters, background, frame, etc., that display the information of the corresponding block, based on the section of the rate of change for which the boundary value is set in advance, or the section for which the boundary value is set as a ratio to the maximum rate of change. Typically, the program display unit 136 may be configured to classify the rate of change of the rotation number and the output value into three sections each, and to display the characters or background of the blocks with a small rate of change in blue, those with a moderate rate of change in yellow, and those with a large rate of change in red. The color of the block is preferably determined by the higher rate of change between the rotation number section and the output value section. In this manner, the program display unit 136 displays the program portion information in a manner that allows for distinguishing the magnitude of the rate of change of at least one of the rotation number or the output value for each block, thereby allowing for easily identifying the blocks that cause a significant change in at least one of the rotation number or the output value. The rate of change may be the maximum rate of change within the block, or may be the rate of change between the representative values of the block.

The program display unit 136 may change the display mode for the program portion information in a manner that allows for distinguishing the load level determined based on the combination of the rotation number and the output value. For example, the program display unit 136 may indicate the load zone, to which the combination of the rotation number and the output value associated with the displayed block belongs, in the graph display unit 137, by difference in color or pattern of the characters, background, or frame displaying the block information.

The program display unit 136 may change the display mode based on the state value, thereby allowing for distinguishing the magnitude of the state value either continuously or stepwise. The program display unit 136 may add characters indicating the section of the value or magnitude of the state value to each block, and may indicate the magnitude of the state value by difference in color or pattern of the characters, background, or frame displaying each block information. Typically, the possible range of the state value is divided into three or more sections, and the program display unit 136 may be configured to change the display mode of the block, based on which section the state value belongs to. In this case, the program display unit 136 may be capable of setting the boundary value of the state value which changes the display mode of the block in accordance with a user input.

As described later, the program display unit 136 may distinguishably display the block associated with the combination of the rotation number and the output value whose difference from the coordinate position selected in the graph display unit 137 is less than or equal to a predetermined margin amount. Clearly displaying the block that produces a result to which the user will pay attention in the graph display unit 137 enables the user to easily understand the problematic points in the machining program. By setting a margin amount for selecting a coordinate position, blocks including combinations of approximate rotation number and output value can be suggested as candidates, allowing for rough selection.

The graph display unit 137 displays a graph on the display screen of the display device 30, plotting markers indicating combinations of the rotation number and the output value in a graph area with one axis representing rotation number and the other axis representing output value. The graph display unit 137 may display a graph for a single output value, or graphs for a plurality of output values side by side. The graph display unit 137 preferably provides the aforementioned function of selecting a coordinate position.

In order to clarify the relationship between the machining program and the rotation number and output value, the program display unit 136 and the graph display unit 137 preferably display the program portion information and the graph simultaneously on the same screen, as illustrated in FIG. 2. The program display unit 136 and the graph display unit 137 may display exclusively. In this case, when switching to the screen display by the graph display unit 137, the rotation number and the output value corresponding to the block selected by the program display unit 136 may be plotted. Conversely, when switching to the screen display by the program display unit 136, the program portion information corresponding to the rotation number and the output value near the coordinate value selected by the graph display unit 137 may be highlighted.

The graph display unit 137 includes: a graph area setting unit 1371 that divides the graph area into a plurality of load zones and distinguishably displays the load zones; and a plot unit 1372 that plots the markers by changing the display mode, based on the state value.

The graph area setting unit 1371 divides the graph area into a plurality of load zones with different load levels, based on the plurality of time ratings of the spindle motor 20, regarding the expected combinations of the rotation number and the output value. This enables the user to easily understand the danger level of the spindle motor 20.

The graph area setting unit 1371 preferably displays the plurality of load zones distinguishably using colors or patterns. Using colors or patterns allows for easily understanding which load zone the combination of the rotation number and the output value belongs to. Using intuitive colors or patterns, such as blue, yellow, and red, to indicate the load level of the zones helps the user easily understand the danger level of the operational state of the spindle motor 20.

If the combination of the rotational speed and the output value of the spindle motor 20 remains within the continuous rating, the load on the spindle motor 20 can be sustained indefinitely in that operational state. Therefore, the upper limit of the lowest load zone is preferably represented by a curve indicating the continuous rating.

The graph area setting unit 1371 preferably forms a boundary of one of the plurality of load zones, preferably the lower limit of the load zone with the highest load level, by connecting the maximum values of the plurality of time ratings (such as short-time ratings and repetitive ratings with different load time ratios) at the same rotation number. The combination of the rotational speed and the output value plotted in the area beyond this boundary line means a dangerous output condition that can immediately cause a failure. Conversely, staying within this boundary may indicate that short-term operation will not cause issues.

The graph area setting unit 1371 may be configured to be capable of selecting the boundary of at least one of the plurality of load zones in accordance with a user input. Specifically, the boundaries of the load zones can be selected from the continuous rating, the maximum value of the plurality of time ratings, the plurality of short-time ratings with different load times, and the plurality of repetitive ratings with different load time ratios. This allows for setting the load zones considered appropriate, based on the machining content of the machine tool 1, allowing for more appropriately understanding the danger level of the spindle motor 20.

The plot unit 1372 plots the combination of the rotation number and the output value while indicating the magnitude of the state value through differences in marker appearances such as shape, size, color, and pattern (as illustrated in FIG. 2 with hatching inside the circular outer border). This allows the user to understand the operational state of the spindle motor 20 at that time indicated by the rotation number and the output value, as well as the state value that may be influenced by the previous operational state of the spindle motor 20. For example, even if the state value indicates that the temperature of the spindle motor 20 is high, as long as the load level at that time is low, the user may be able to determine that there is no danger of further increase in the temperature of the spindle motor 20. Conversely, even if the load level at that time is not very high, the user may be able to determine that overheating may soon occur if the operational state continues. The marker may include an outer border that easily differentiates from the colors or patterns of the graph area, and a filled portion indicating the state value. Thus, the plot unit 1372 indicates the state values through the marker appearances, thereby allowing the user to understand the operational state of the spindle motor 20 in a multifaceted manner.

The plot unit 1372 may change the size, color, etc., of the marker continuously based on the state value; however, the possible range of the state value is divided into three or more sections, and the marker appearance is preferably determined based on which section the state value belongs to. By changing the marker appearance stepwise, the magnitude of the state value can be presented more clearly. The sections of the state value may be pre-set or dynamically changed. For example, when the estimated time until reaching the overheating temperature is used as the state value, the state value (estimated time) at the moment when the combination of the rotation number and the output value exceeds the continuous rating is used as the maximum value within the possible range of the state value, and a predetermined ratio to this maximum value may be used as the boundary value for the section of the state value. Typically, the plot unit 1372 may be configured to divide the possible range of the state value into three sections by setting the boundary values to trisect the maximum value.

The plot unit 1372 may be configured to be capable of setting the boundary value of the state value which changes the marker appearances in accordance with a user input. The boundary value may be specified as an absolute value or as a ratio to the maximum value. The user may select the boundary value from the plurality of pre-set options. This allows for changing the marker appearances at timings considered appropriate, considering the machining content of the machine tool 1, enabling the user to understand the danger level of the spindle motor 20 more appropriately.

As described above, when the position in the machining program is selected or edited in the program display unit 136, the plot unit 1372 is preferably configured to selectively plot the rotation number and the output value corresponding to the selected or edited position in the machining program. Especially when the user selects a plurality of blocks in the program display unit 136, the plot unit 1372 preferably simultaneously plots or continuously plots and animates the rotation number and the output value corresponding to the plurality of selected blocks. This allows the user to easily check the rotation number, the output value, and the state value of the spindle motor 20 in the blocks to be checked or edited in the machining program.

The numerical control device 10 according to the present embodiment includes the graph display unit 137 that includes: the graph area setting unit 1371 that divides the graph area into a plurality of load zones with different load levels, based on the plurality of time ratings of the spindle motor 20, regarding the expected combinations of the rotation number and the output value of the spindle motor 20, and distinguishably displays the plurality of load zones; and the plot unit 1372 that plots the markers by changing the appearances of the markers based on the state value. This enables the user to easily understand the safety of the load condition of the spindle motor 20.

Although the embodiments of the present disclosure have been described above, the present invention is not limited to the embodiments described above. The effects described in the above embodiments are merely examples of the preferred effects resulting from the present invention, and the effects of the present invention are not limited to those described in the above embodiments.

The motor monitoring device according to the present disclosure may be provided independently of the numerical control device that controls the machine tool, and may be used for monitoring the motors other than the spindle motor of the machine tool, such as the motor of a kneading machine. For example, the motor monitoring device according to the present disclosure may add the functions of the motor monitoring unit described in the above embodiments to a management computer that manages one or more numerical control devices, such as a control device for a kneading machine or a management computer that manages such a control device.

The motor monitoring device according to the present disclosure may omit the information storage unit and the program display unit. In other words, the motor monitoring device according to the present disclosure may be configured to display the load condition of the spindle motor in real time.

### EXPLANATION OF REFERENCE NUMERALS

1: machine tool
10: numerical control device (motor monitoring device)
11: program storage unit
12: motor control unit
13: motor monitoring unit
131: program acquisition unit
132: rotation number acquisition unit
133: output value acquisition unit
134: state value acquisition unit
135: information storage unit
136: program display unit
137: graph display unit
1371: graph area setting unit
1372: plot unit
20: spindle motor
21: rotation number detector
22: current detector
23: temperature detector
30: display device
40: input device

1. A motor monitoring device, comprising:
a rotation number acquisition unit that acquires a rotation number of a motor;
an output value acquisition unit that acquires an output value of the motor;
a state value acquisition unit that acquires a state value indicating a condition of the motor; and
a graph display unit that plots a marker indicating a combination of the rotation number and the output value in a graph area where one axis represents the rotation number and an other axis represents the output value;
wherein the graph display unit includes:
a graph area setting unit that divides the graph area into a plurality of load zones with different load levels, based on a plurality of time ratings of the motor, regarding an expected combination of the rotation number and the output value, and distinguishably displays the plurality of load zones; and
a plot unit that plots the marker by changing an appearance of the marker, based on the state value.

2. The motor monitoring device according to claim 1, wherein the graph area setting unit forms a boundary of one of the plurality of load zones by connecting maximum values of the plurality of time ratings at the same rotation number.

3. The motor monitoring device according to claim 1, wherein the graph area setting unit selects a boundary of at least one of the plurality of load zones in accordance with a user input.

4. The motor monitoring device according to claim 1, wherein the graph area setting unit distinguishably displays the plurality of load zones using colors or patterns.

5. The motor monitoring device according to claim 1, wherein a possible range of the state value is divided into three or more sections, and the plot unit determines an appearance of the marker, based on which section the state value belongs to.

6. The motor monitoring device according to claim 1, wherein the plot unit is capable of setting a boundary value of the state value which changes the appearance of the marker in accordance with a user input.

7. The motor monitoring device according to claim 1, wherein the state value acquisition unit calculates, as the state value, an estimated time until the motor reaches an overheating temperature in a case where the motor maintains the rotation number and the output value at present values.
